(19) United States
(12) Patent Application Publication
(10) Pub. No.: US 2013/0286297 A1
(43) Pub. Date: Oct. 31, 2013

(54) TELEVISION RECEIVER AND ELECTRONIC DEVICE

(71) Applicant: KABUSHIKI KAISHA TOSHIBA, Tokyo (JP)

(72) Inventor: Nobuto FUJIWARA, Tokyo (JP)

(73) Assignee: Kabushiki Kaisha Toshiba, Tokyo (JP)

(21) Appl. No.: 13/727,881

(22) Filed: Dec. 27, 2012

(30) Foreign Application Priority Data
Apr. 27, 2012 (JP) 2012-102637

(51) Int. Cl. H04N 5/64; H05K 7/20

(52) U.S. Cl. CPC H04N 5/64; H05K 7/20145
USPC 348/836; 361/695

(57) ABSTRACT

According to one embodiment, television receiver includes: display; housing; fan; first wall; second wall; and third wall. The housing houses at least a portion of the display. The fan is opposite a screen of the display with respect to the display, and is rotatable in the housing. The first wall of the housing including a vent hole overlapping with the fan, covers the fan and a side of the display opposite the screen, and constitutes one portion of a case of the fan. The second wall is on an inner side of the housing with respect to the first wall and on a side of the fan opposite the first wall. The second wall attaches to the first wall. The second wall constitutes other portion of the case. The third wall extends between the first wall and the second wall.

### CROSS-REFERENCE TO RELATED APPLICATIONS

This application is based upon and claims the benefit of priority from Japanese Patent Application No. 2012-102637, filed on Apr. 27, 2012, the entire contents of which are incorporated herein by reference.

### FIELD

Embodiments described herein relate generally to a television receiver and an electronic device.

### BACKGROUND

Conventionally, there is known an electronic device in which a fan is provided in a housing.

In an electronic device provided with a fan, it is preferable that novel arrangements relating to the fan allow advantages such as a simpler structure and reduce disadvantages.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary side view of the television receiver in the first embodiment;

FIG. 3 is an exemplary schematic cross-sectional view taken along line of FIG. 1, in the first embodiment;

FIG. 4 is an exemplary plan view f a fan comprised in the television receiver in the first embodiment;

FIG. 5 is an exemplary front view of a fan unit comprised in the television receiver in the first embodiment;

FIG. 6 is an exemplary cross-sectional view of a television receiver taken at a position the same as that of FIG. 3, according to a second embodiment;

FIG. 7 is an exemplary perspective view of an electronic device according to a third embodiment;

FIG. 8 is an exemplary plan view (bottom view) of a second housing of the electronic device in the third embodiment;

FIG. 9 is an exemplary cross-sectional view taken along line IX-IX of FIG. 8, in the third embodiment;

FIG. 10 is an exemplary cross-sectional view of an electronic device taken at a position the same as that of FIG. 9, according to a first modification of the third embodiment;

FIG. 11 is an exemplary cross-sectional view of a third wall of an electronic device according to a second modification of the third embodiment;

FIG. 12 is an exemplary cross-sectional view of a third wall of an electronic device according to a third modification of the third embodiment;

FIG. 13 is an exemplary cross-sectional view of a bearing of a fan of an electronic device according to a fourth modification of the third embodiment; and

FIG. 14 is an exemplary cross-sectional view of a bearing of a fan of an electronic device according to a fifth modification of the third embodiment.

### DETAILED DESCRIPTION

In general, according to one embodiment, a television receiver comprises: a display; a housing; a fan; a first wall; a second wall; and a third wall. The display comprises a screen. The housing is configured to house at least a portion of the display. The fan is opposite the screen with respect to the display, and configured to be rotatable in the housing. The first wall of the housing comprising a vent hole overlapping with the fan, configured to cover the fan and a side of the display opposite the screen, and to constitute one portion of a case of the fan. The second wall is on an inner side of the housing with respect to the first wall and on a side of the fan opposite the first wall. Here, the second wall is configured to attach to the first wall. Further, the second wall is configured to constitute other portion of the case of the fan. The third wall is configured to extend between the first wall and the second wall.

Exemplary embodiments, which will be described below, comprise the same components. In the following, the same components are represented with common symbols, and the repetition of explanation is omitted.

The following embodiments exemplify cases in which an electronic device is configured as a television receiver or a so-called laptop (clamshell) personal computer. However, the electronic devices in the embodiments are not limited thereto. The electronic devices in the embodiments can be configured as an electronic device comprising a fan, more concretely as a so-called desktop or tablet (slate) personal computer, a Smart TV, an image display device, or a projector, for example.

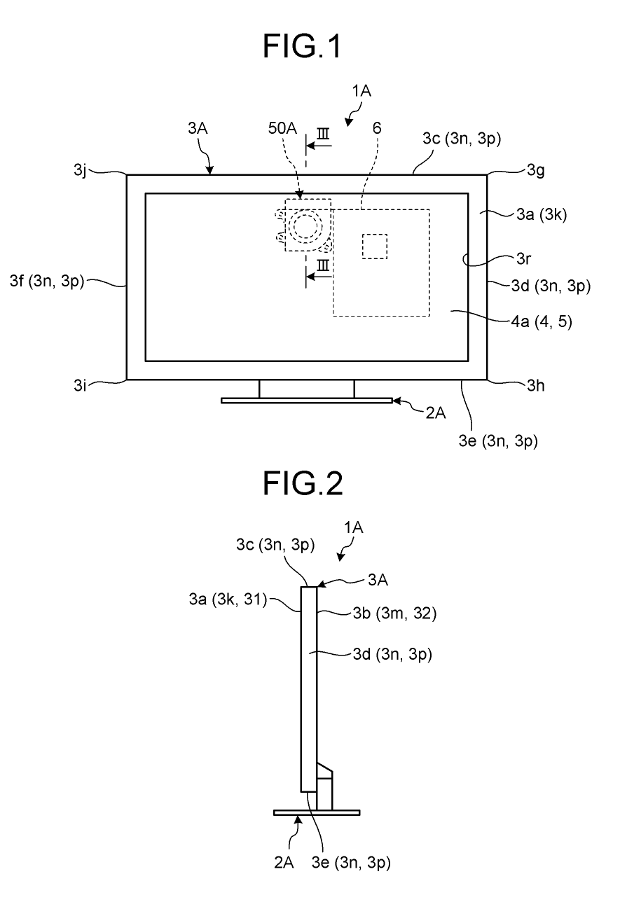

In a first embodiment, as an example, a television receiver 1A (an electronic device) comprises a support portion 2A, and a housing 3A, as illustrated in FIGS. 1 and 2. To be more specific, the housing 3A houses at least a portion of a display 4. The support portion 2A (a stand, a base, a leg) supports the housing 3A. The support portion 2A can support the housing 3A in a movable manner (rotatable manner). In this case, the motion of the housing 3A is of tilt, pivot, swivel, etc.

In the first embodiment, as an example, the housing 3A is quadrangular (rectangular as an example in the first embodiment) in a front view and a rear view, as illustrated in FIG. 1. In the first embodiment, as an example, the housing 3A is thin flat rectangular parallelepiped in a front-back direction, as illustrated in FIG. 2. The housing 3A has a face 3a (an anterior face, an upper face, a front face, a face portion) and an opposite face 3b (a back face, an under face, a rear face, a face portion). The face 3a and the face 3b are nearly parallel. As illustrated in FIG. 1, in a front view, the housing 3A has four ends 3c to 3f (sides, edges), and four corners 3g to 3j (apexes, curves, ends). The ends 3c and 3e are examples of long sides, while the ends 3d and 3f are examples of short sides.

The housing 3A has a wall 3k (a part, a plate, a frame, a front wall, a surface wall, a top wall) comprising the face 3a, and a wall 3m (a portion, a plate, a back wall, a rear wall, a bottom wall) comprising the face 3b, as an example. The walls 3k and 3m are quadrangular (rectangular as an example in the first embodiment). The housing 3A has four walls 3n (portions, plates, side walls, end walls, standing walls, extending portions) comprising a face 3p (a side face, a peripheral face) extending between the wall 3k and the wall 3m. The wall 3k is provided with a quadrangular opening 3r, for example. Thus, the wall 3k is quadrangular and is of frame.

The housing 3A can be constituted by a combination of a plurality of components (divided bodies). In the first embodiment, as an example, the housing 3A comprises a first housing member 31 (a first portion, a front-side member, a mask, a mask portion, a cover, a front cover, a cover portion, a first area) comprising at least the wall 3k, and a second housing member 32 (a second portion, a back-side member, a base, a base portion, a bottom, a bottom portion, a cover, a rear cover, a cover portion, a second area) comprising at least the wall 3m. The walls 3n are included in at least one of the first housing member 31 and the second housing member 32 (in the second housing member 32, for example). Separately from the first housing member 31 and the second housing member 32, the housing 3A can comprise a third housing member (a third portion, an intermediate member, a spacing member, a barrier member, a wall member, an interposed member, an inner plate, a middle plate, a middle frame, a third area (not illustrated)), a fourth housing member (a fourth portion, an intermediate member, a spacing member, a barrier member, a wall member, an interposed member, a covering member, a shield, a fourth area (not illustrated)), and other members that are interposed between the housing members 31, 32. The housing 3A can be formed of metallic or synthetic resin material, for example. Inside of the housing 3A such as in the first housing member 31 and the second housing member 32, wall portions such as ribs (projecting portions, projecting walls (not illustrated)) can be provided. These walls make the housing 3A more rigid.

In the first embodiment, as an example, the faces 3b and 3p, etc., of the housing 3A can be provided with a connecter, an operation portion, (not illustrated) etc. The connector may be a connector for a power cable, a universal serial bus (USB) connector, a card connector, or a connector for earphones, or a microphone, for example. The operation portion may be of a push button, a push switch, a slide switch, a pointing device, or a dial, for example. The face 3a can be provided with a camera module (a camera, an imaging device (not illustrated)).

In the first embodiment, as an example, a screen 4a positioned on the side of the face 3a of the display 4 (a display module, a display, a panel) is exposed to the front side (outside) of the housing 3A through the opening 3r, as illustrated in FIG. 1. A user, for example, can visually recognize the screen 4a through the opening 3r from the front side. The display 4 is quadrangular (rectangular as an example in the first embodiment) in a front view. The display 4 is thin flat rectangular parallelepiped in a front-back direction. The display 4 is a liquid crystal display (LCD), or an organic electro-luminescent display (OELD), for example.

In the first embodiment, as an example, on the front side (the surface side, the side of the wall 3k) of the display 4, a touch panel 5 (an input operation panel, a touch sensor, an operation face, a cover, for example) is provided. The touch panel 5 is transparent relatively-thin quadrangular, and covers the screen 4a. A user, for example, touches, pushes, rubs the touch panel 5 with a finger, a piece (a stylus, for example (not illustrated)), etc., or moves a finger, a stylus, etc., in the vicinity of the touch panel 5, for example, so as to perform input processing. The light emitted from the screen 4a of the display 4 passes through the touch panel 5, and is then let out to the front side (outside) of the housing 3A through the opening 3r of the wall 3k.

In the first embodiment, as an example, the housing 3A houses, on the back side (the reverse side, the rear side, the side of the wall 3m, the side opposite the screen 4a) of the display 4, one or more substrate 6 (a circuit board, a control board, a main board, an electrical component, a component). The substrate 6 is provided in parallel with the display 4. The substrate 6 is spaced from the walls 3k, 3m, 3n, etc., that is, the substrate 6 is arranged with space (gaps) from the walls 3k, 3m, 3n, etc.

In the first embodiment, as an example, a plurality of components (not illustrated) such as a central processing unit (CPU), a graphic controller, power circuit parts, a plat form controller hub (PCH), a memory slot connector, an LCD connector, an input/output (I/O) connector, a power coil, an element, and a connector, can be mounted on the substrate 6. A control circuit can comprise an image signal processing circuit, a tuner, a high-definition multimedia interface (HDMI) signal processor, an audio video (AV) input terminal, a remote control signal receiving module, a controller, a selector, an on-screen display interface, a memory (a read only memory (ROM), a random access memory (RAM), a hard disk drive (HDD), a solid state drive (SSD), for example), a voice signal processing circuit, etc. The control circuit controls the output of images (moving images, still images, etc.) on the screen 4a of the display 4, the output of voice from a speaker (not illustrated), the emission of light from a light emitting diode (LED) (not illustrated), etc. The display 4, the speaker, the LED, etc., are examples of an output module.

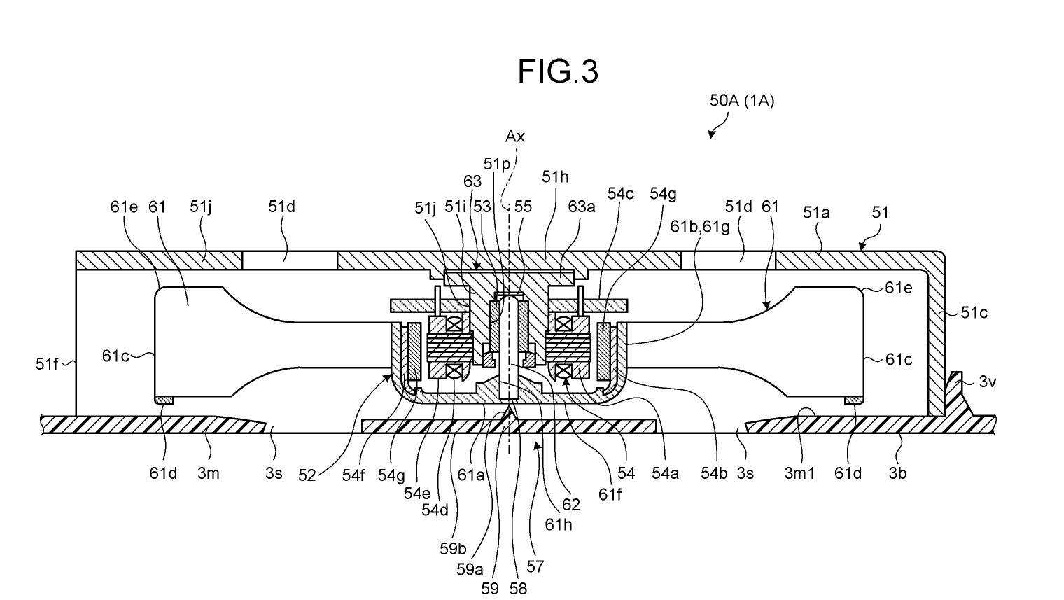

In the first embodiment, as an example, a fan unit 50A is provided, as illustrated in FIGS. 1 and 3. A fan 61 is rotated, so that the fan unit 50A (an air cooling device, a cooling device) takes in and exhausts air. The air flow formed by the rotation of the fan 61 cools down a heating element (a part, an electronic part, an electrical part, a heating portion) in the housing 3A, a heat exchanger (a heat exchanging part, a radiating fin) of the cooling device, etc.

In the first embodiment, as an example, the fan unit 50A is attached on a face 3m1 (an inner face, an inner face of the housing) opposite the face 3b of the wall 3m (an outer wall, a top wall, a bottom wall, a first wall) of the housing 3A, as illustrated in FIG. 3. In the first embodiment, as an example, the fan unit 50A is open to one side in an axis direction, and does not have a wall on the one side in an axis direction. In other words, the wall 3m is configured as a portion (a wall on one side in an axis direction of a rotation axis Ax) of a case (a housing) of the fan unit 50A. The wall 3m covers one side in an axis direction of the fan 61. The wall 3m is provided with vent holes 3s.

That is, in the first embodiment, as an example, a wall 51a (an inner wall, a top wall, a bottom wall, a second wall, a case) and a wall 51c (a side wall, a peripheral wall, an extending portion, a third wall, a case) are integrated so as to configure a case component 51. In the first embodiment, as an example, the case component 51 is attached on the face 3m1 of the wall 3m with fasters 30 (fixtures (screws, for example)), as illustrated in FIG. 5.

The wall 51a is provided on the side of the fan 61 opposite the wall 3m (the other side in an axis direction of the rotation axis Ax, the inner side of the housing), and extends in a direction intersecting with (orthogonal to) the rotation axis Ax. That is, the wall 51a covers the inner side of the housing of the fan 61 (the other side in the axis direction). The wall 51a and the wall 3m are nearly parallel. The wall 51a is provided with vent holes 51d. The wall 51c extends between the wall 3m and the wall 51a. The wall 51c is provided with a vent hole 51f. The vent hole 51f is provided on one side in a radial direction of the fan 61 (on the upper side of FIG. 1 as an example in the first embodiment). That is, the wall 51c covers the outer side in a radial direction of the fan 61, except a part at which the vent hole 51f is provided.

The vent holes 3s and 51d overlap with the fan 61 in a thickness direction of the fan unit 50A (the axis direction of the rotation axis Ax, a thickness direction of the housing 3A, an overlapping direction (a facing direction) of the wall 3m and the wall 51a). The vent hole 51f overlaps with the fan 61 in a direction orthogonal to a thickness direction of the fan unit 50A (a radial direction of the rotation axis Ax, a direction along the face 3m1). It is possible to appropriately change an air flowing direction, depending on a design of the fan 61.

A rotator 52 (a rotating portion, a movable portion, a rotor) has the fan 61, and a shaft 62 (a shaft portion, a pillar portion), as illustrated in FIG. 3. The rotator 52 is housed in the case component 51. The rotator 52 rotates with the shaft 62 as a center. In other words, the shaft 62 extends along a thickness direction of the fan unit 50A.

The fan 61 has a base 61a at which one end of the shaft 62 is fixed and a plurality of blades 61c extending from a peripheral face 61b of the base 61a. The fan 61 is formed of synthetic resin or metallic material. The base 61a is formed in a cup-like shape, and is positioned so that the opening portion thereof faces the wall 51a. The base 61a has a disk-formed base wall 61f, and a side wall 61g extending from the periphery of the base wall 61f toward the wall 51a. The outer peripheral face of the side wall 61g is a peripheral face 61b of the base 61a. On the inner face of the base wall 61f, a concaved shaft-fixing portion 61h is provided. One end of the shaft 62 is inserted into the shaft-fixing portion 61h and fixed therein.

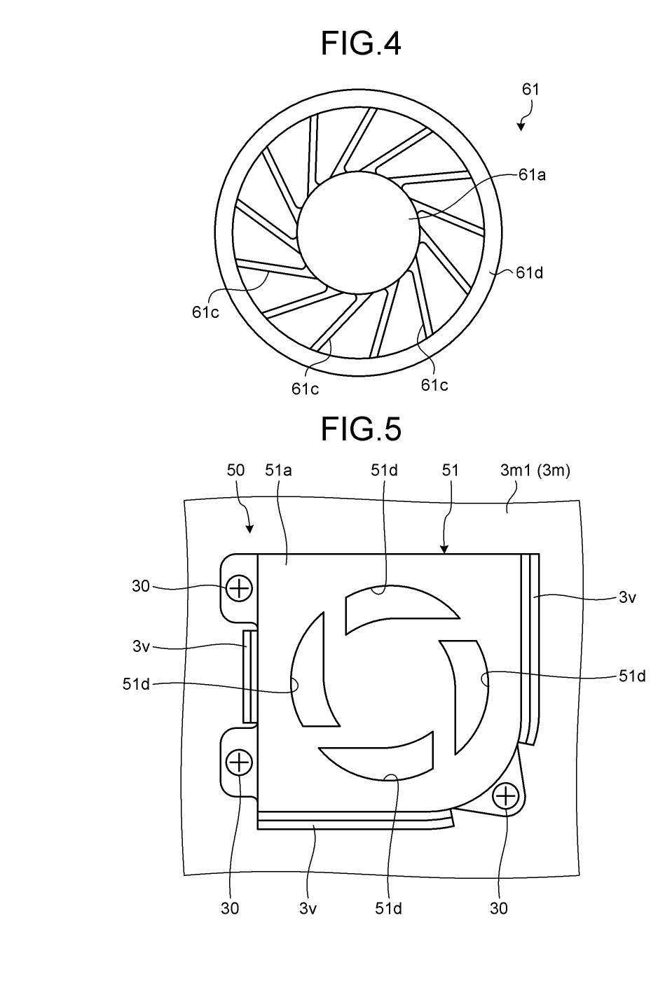

The fan 61 has an annular connecting member 61d on the outer periphery thereof, as illustrated in FIG. 4. The connecting member 61d connects the outer edges on the axis direction side of the blades 61c. An end 61e of the blade 61c is curved (inclined) so as to separate from the wall 51a as a position moves from the inner periphery to the outer periphery.

A bearing 53 is provided on a base component 63 fixed to the case component 51 to support the shaft 62 in a rotatable manner. The base component 63 is fixed (attached) to the case component 51 by gluing, or screwing, for example. The base component 63 can be formed integrally with the case component 51. The bearing 53 has a cylindrical form. The bearing 53 can be configured as a needle bearing, a ball bearing, a slide bearing, a fluid bearing, or an oil-impregnated bearing, for example. The bearing 53 is engaged with an opening 51p formed in a cylinder 51i standing on a base 63a of the base component 63, and thus fixed to the base 63a. On a bottom face of the cylinder 51i, a thrust plate 55 is fixed. The thrust plate 55 supports an end face in an axis direction of the shaft 62. At least a portion of the shaft 62 is housed in the opening 51p of the bearing 53 provided on the base 63a. The bearing 53 is an example of a support portion in which at least a portion of the rotator 52 as a rotating portion is housed and the rotator 52 is supported in a rotatable manner.

As illustrated in FIG. 3, a motor 54 has a stator 54a, a rotor 54b surrounding the stator 54a, and a circuit board 54c. The stator 54a has an iron core 54e with winding wire 54d. The rotor 54b has a cylindrical yoke 54f, and a plurality of magnets 54g fixed on an inner peripheral face of the yoke 54f along a circumferential direction with mutual intervals. The yoke 54f is fixed to the inner peripheral side of the side wall 61g of the base 61a. A lead 56 is connected to the circuit board 54c, and the circuit board 54c transfers electric power supplied from the lead 56 to the winding wire 54d. In the motor 54, the electromagnetic action of the magnet 54g and the stator 54a facing the magnet 54g rotates the rotor 54b. Then, the rotation of the rotor 54b rotates the rotator 52.

The fan unit 50A is provided with a movement restricting structure 57 (a return-preventing portion, a return-preventing structure, a return-preventing mechanism) restricting the movement of the rotator 52 to a direction separating from the bearing 53. The movement restricting structure 57 has a contact portion 58 (a support portion) provided to the rotator 52, and a restricting portion 59 (a support portion) provided to the wall 3m.

The contact portion 58 is provided in the base 61a. In detail, an outer face in a center portion of the base wall 61f of the base 61a constitutes the contact portion 58.

The restricting portion 59 comprises a projecting portion 59a (a protrusion) and a support portion 59b. The projecting portion 59a projects from the support portion 59b toward the contact portion 58 and toward inside the housing. The projecting portion 59a can be connected to or disconnected from the contact portion 58.

Here, usually, with attracting force (magnetic force) of the magnet 54g on the stator 54a, the rotator 52 rotates or stops while maintaining a determined distance between the projecting portion 59a and the contact portion 58. However, external force, etc., is exerted on the fan unit 50A, so that, resisting the attracting force, the rotator 52 may be moved to a direction separating from the bearing 53. When an impact is applied to the fan unit 50A and the rotator 52 is moved to a direction separating from the bearing 53, the contact portion 58 provided in the rotator 52 comes into contact with the restricting portion 59 provided to the wall 3m. Thus, the restricting portion 59 restricts the movement of the rotator 52 to a direction separating from the bearing 53. In other words, the restricting portion 59 restricts, through contact with the contact portion 58, the movement of the shaft 62 as the pillar portion to a direction separating from the opening 51p. When the influence of external force, etc., is disappeared, the rotator 52 returns, with attracting force (magnetic force) of the magnet 54g, to a position at which a determined distance between the projecting portion 59a and the contact portion 58 is maintained. In this manner, the movement of the rotator 52 along an axis direction is restricted in the first embodiment.

In the first embodiment, as an example, a wall 3v (a cover) covering a portion of the wall 51c projects from the wall 3m of the housing 3A, as illustrated in FIGS. 3 and 5. The wall 3v covers a gap between the wall 51c and the wall 3m. Thus, in the first embodiment, as an example, the leak of air from the gap can be prevented. Therefore, as an example, it is possible to prevent the deterioration of operating efficiency in operation (rotation of the fan 61) of the fan unit 50A and, in addition, the deterioration of cooling efficiency thereof. The wall 3v functions as a position determining portion (guide) when the case component 51 (fan unit 50A) is attached to the housing 3A. In other words, the side wall (a third wall) of the fan unit 50A is configured by making the wall 51c of the case component 51 overlap with the wall 3v of the housing 3A in an axis direction of the rotation axis Ax. In this manner, with the arrangement in which the walls 51c and 3v are overlapped with each other, air resistance in such a portion increases, and thus air hardly leaks.

As described above, in the first embodiment, as an example, the case of the fan unit 50A is configured by the wall 3m of the housing 3A of the television receiver 1A. Therefore, in the first embodiment, as an example, it is possible to decrease the number of parts in the fan unit 50A or simplify the structure of the fan unit 50A. In addition, in the first embodiment, as an example, it is possible to make the thickness of the fan unit 50A thinner, and thus make the thickness of the housing 3A thinner as an example.

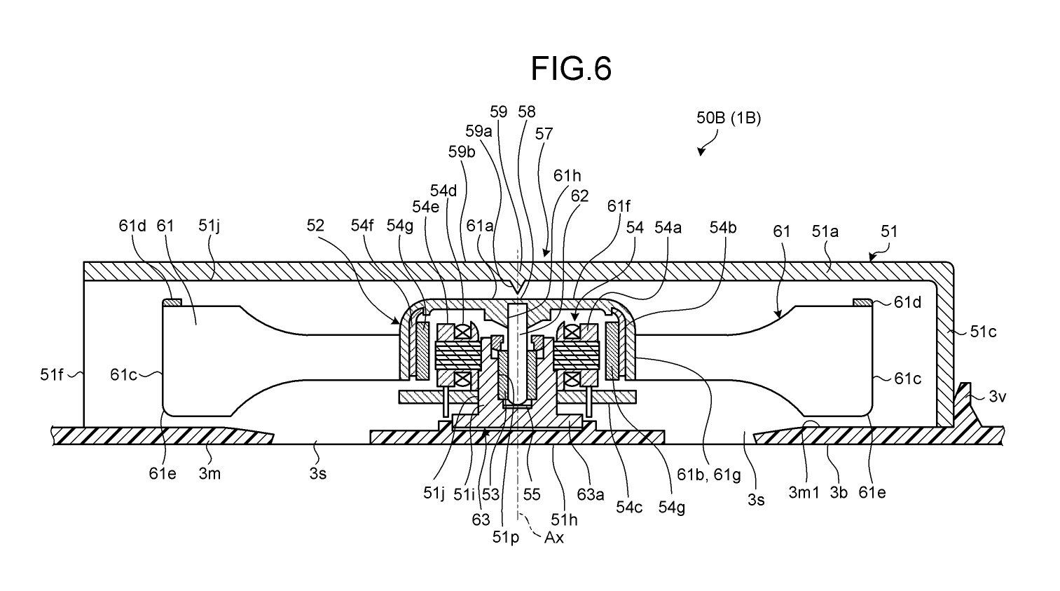

In a television receiver 1B in a second embodiment, as an example, the base component 63 supporting the motor 54 and the fan 61 of a fan unit 50B is fixed not to the case component 51 but to the wall 3m of a housing 3B, as illustrated in FIG. 6. The base component 63 is fixed (attached) to the wall 3m by gluing, or screwing, for example. Therefore, in the second embodiment, as an example, a direction in an axis direction of the motor 54 and the fan 61 is opposite from in the television receiver 1A in the first embodiment. However, also with the arrangement, the wall in an axis direction of the fan unit 50B is also used as the wall 3m of the housing 3B. Therefore, also in the second embodiment, the same results (effects) as in the first embodiment can be obtained.

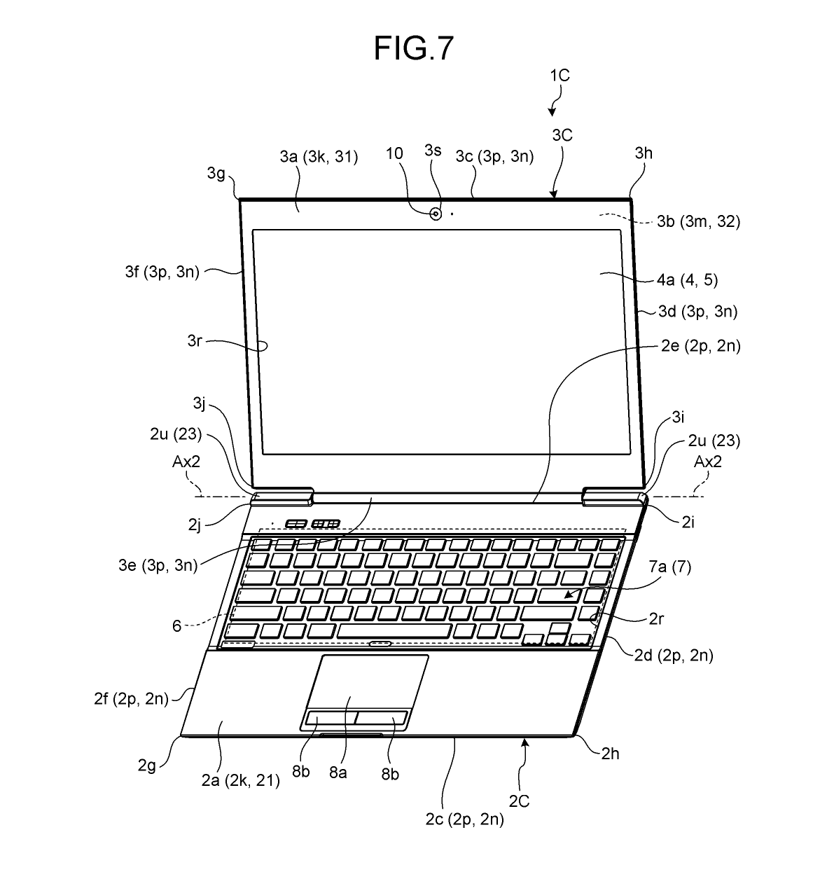

In a third embodiment, as an example, an electronic device 1C comprises a first housing 3C and a second housing 2C as illustrated in FIG. 7. To be more specific, the first housing 3C (a first portion) houses at least a portion of the display 4. The first housing 3C is provided with the transparent touch panel 5 (a touch sensor, an input operation portion, an input receiving portion, an input portion) overlapped with the display 4. A user, for example, can visually recognize images (pictures) displayed on the screen 4a of the display 4 through the touch panel 5.

As illustrated in FIG. 7, the second housing 2C (a second portion) houses the substrate 6. The second housing 2C is provided with a keyboard 7 (an input operation portion, a first input operation portion, an input receiving portion, an input portion), a pointing device 8a (an input operation portion, a second input operation portion, an input receiving portion, an input portion), click buttons 8b (input operation portions, input receiving portions, input portions), etc.

The first housing 3C and the second housing 2C are connected to each other in a rotatable manner with a hinge mechanism 9 (a hinge, a connecting portion, a coupling portion, a rotatable support portion, a connecting mechanism, a coupling mechanism, a rotatable support mechanism). The first housing 3C and the second housing 2C are connected to each other in a rotatable manner with the hinge mechanism 9 at least between an open state illustrated in FIG. 7 and a folded state (not illustrated). In the third embodiment, as an example, the hinge mechanism 9 connects the first housing 3C and the second housing 2C in a rotatable manner around a rotation axis Ax2.

The screen 4a of the display 4 can be visually recognized through the opening 3r provided on the face 3a (an anterior face, an upper face, a front face, a face portion) of the first housing 3C. The keyboard 7, the pointing device 8a, the click buttons 8b, etc., are exposed on a face 2a (an anterior face, an upper face, a front face, a face portion) of the second housing 2C. In the folded state, the face 3a of the first housing 3C and the face 2a of the second housing 2C are overlapped with each other, and the screen 4a, the keyboard 7, the pointing device 8a, the click buttons 8b, etc., are hidden by the first housing 3C and the second housing 2C. In the open state, the face 3a of the first housing 3C and the face 2a of the second housing 2C are exposed, and the screen 4a, the keyboard 7, the pointing device 8a, the click buttons 8b, etc., become available (visually recognizable or operational). One side in a thickness direction of the first housing 3C may be covered by a face of the touch panel. In this case, the face of the touch panel is a face of the first housing. The second housing 2C may be provided with a display device having a touch panel (not illustrated) instead of the keyboard. Furthermore, one side in a thickness direction of the second housing 2C may be covered by a face of the touch panel. In this case, the face of the touch panel is a face of the second housing.

In the third embodiment, as an example, the first housing 3C is quadrangular (rectangular as an example in the third embodiment) in a front view and a rear view, as illustrated in FIG. 7. In the third embodiment, as an example, the first housing 3C is thin flat rectangular parallelepiped. The first housing 3C has the face 3a and the opposite face 3b (a back face, an under face, a rear face, a face portion). The face 3a and the face 3b are nearly parallel. As illustrated in FIG. 7, the first housing 3C has four ends 3c to 3f (sides, edges), and four corners 3g to 3j (apexes, curves, ends) in a front view. The ends 3c and 3e are examples of long sides, while the ends 3d and 3f are examples of short sides.

The first housing 3C has the wall 3k (a portion, a plate, a frame, a front wall, a surface wall, a top wall) comprising the face 3a, and the wall 3m (a portion, a plate, a back wall, a rear wall, a bottom wall) comprising the face 3b. The walls 3k and 3m are quadrangular (rectangular as an example in the third embodiment). The first housing 3C has four walls 3n (portions, plates, side walls, end walls, standing walls, extending portions) comprising the face 3p (a side face, a peripheral face) extending between the wall 3k and the wall 3m. The wall 3k is provided with the quadrangular opening 3r, for example. Thus, the wall 3k is quadrangular and is of frame.

The first housing 3C can be configured by a combination of a plurality of components (divided bodies). In the third embodiment, as an example, the first housing 3C comprises the first housing member 31 (a first portion, a front-side member, a mask, a mask portion, a cover, a front cover, a cover portion, a first area) comprising at least the wall 3k, and the second housing member 32 (a second portion, a back-side member, a base, a base portion, a bottom, a bottom portion, a cover, a rear cover, a cover portion, a second area) comprising at least the wall 3m. The walls 3n are included in at least one of the first housing member 31 and the second housing member 32 (in the second housing member 32, for example). Separately from the first housing member 31 and the second housing member 32, the first housing 3C can comprise a third housing member (a third portion, an intermediate member, a spacing member, a barrier member, a wall member, an interposed member, an inner plate, a middle plate, a middle frame, a third area (not illustrated)), a fourth housing member (a fourth portion, an intermediate member, a spacing member, a barrier member, a wall member, an interposed member, a covering member, a shield, a fourth area (not illustrated)), and other members that are interposed between the housing members 31 and 32. The first housing 3C can be formed of metallic or synthetic resin material, for example.

In the third embodiment, as an example, the screen 4a positioned on the side of the face 3a of the display 4 (a display portion, a display, a panel) is exposed to the front side (outside) of the first housing 3C through the opening 3r. A user, for example, can visually recognize the screen 4a through the opening 3r from the front side. The display 4 is quadrangular (rectangular as an example in the third embodiment) in a front view. The display 4 is thin flat rectangular parallelepiped in a front-back direction. The display 4 is an LCD, or an OELD, for example.

In the third embodiment, as an example, on the front side (the surface side, the side of the wall 3k) of the display 4, the touch panel 5 (an input operation panel, a touch sensor, an operation face, a cover, for example) is provided. The touch panel 5 is transparent relatively-thin quadrangular, and covers the screen 4a. An operator (a user, etc.) touches, pushes, rubs the touch panel 5 with a finger, a piece (a stylus, for example (not illustrated)), or moves a finger, a stylus, etc., in the vicinity of the touch panel 5, for example, so as to perform input processing. The light emitted from the screen 4a of the display 4 passes through the touch panel 5, and is then let out to the front side (outside) of the first housing 3C through the opening 3r of the wall 3k.

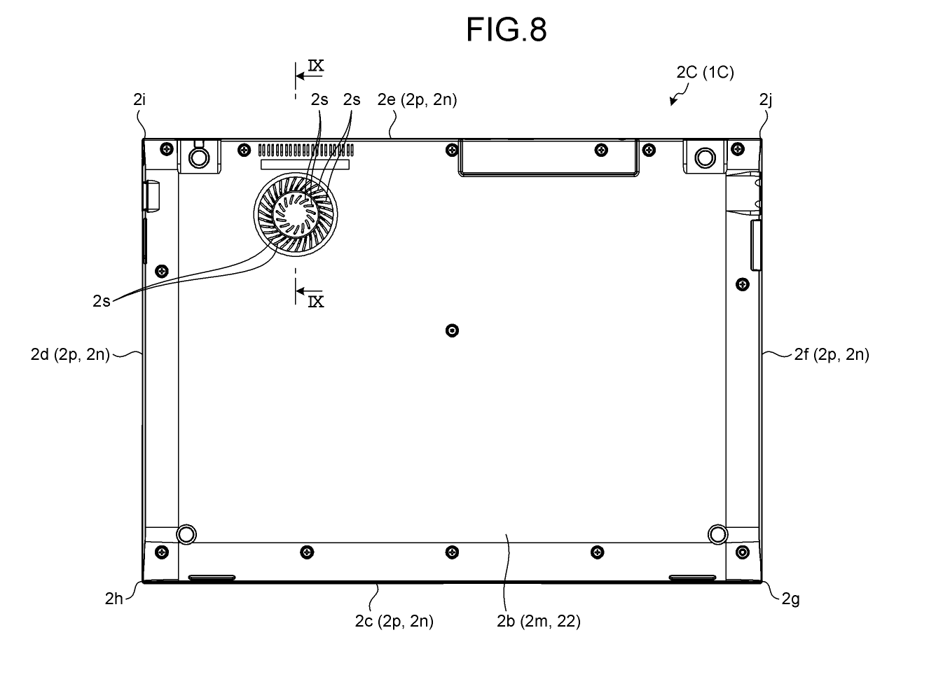

In the third embodiment, as an example, the second housing 2C is quadrangular (rectangular as an example in the third embodiment) in a front view and a rear view, as illustrated in FIGS. 7 and 8. In the third embodiment, as an example, the second housing 2C is thin flat rectangular parallelepiped. The second housing 2C has the face 2a and an opposite face 2b (a back face, an under face, a rear face, a face portion). The face 2a and the face 2b are nearly parallel. In a front view of the face 2a, the second housing 2C has four ends 2c to 2f (sides, edges), and four corners 2g to 2j (apexes, curves, ends). The ends 2c and 2e are examples of long sides, while the ends 2d and 2f are examples of short sides.

The second housing 2C has a wall 2k (a portion, a plate, a frame, a front wall, a surface wall, a top wall) comprising the face 2a, and a wall 2m (a portion, a plate, a back wall, a rear wall, a bottom wall) comprising the face 2b. The walls 2k and 2m are quadrangular (rectangular as an example in the third embodiment). The second housing 2C has four walls 2n (portions, plates, side walls, end walls, standing walls, extending portions) comprising a face 2p (a side face, a peripheral face) extending between the wall 2k and the wall 2m. The wall 2k is provided with a quadrangular opening 2r, for example. Thus, the wall 2k is quadrangular and is of frame.

As an example, the second components (divided bodies). In the third embodiment, as an example, the second housing 2C comprises a first housing member 21 (a first portion, a front-side member, a mask, a mask portion, a cover, a front cover, a cover portion, a first area) comprising at least the wall 2k, and a second housing member 22 (a second portion, a back-side member, a base, a base portion, a bottom, a bottom portion, a cover, a rear cover, a cover portion, a second area) comprising at least the wall 2m. The walls 2n are included in at least one of the first housing member 21 and the second housing member 22 (in the second housing member 22, for example). Separately from the first housing member 21 and the second housing member 22, the second housing 2C can comprise a third housing member (a third portion, an intermediate member, a spacing member, a barrier member, a wall member, an interposed member, an inner plate, a middle plate, a middle frame, a third area (not illustrated)), a fourth housing member (a fourth portion, an intermediate member, a spacing member, a barrier member, a wall member, an interposed member, a covering member, a shield, a fourth area (not illustrated)), and other members that are interposed between the housing members 21, 22. The second housing 2C can be formed of metallic or synthetic resin material, for example.

In the third embodiment, as an example, an operation face 7a (a face, an upper face) of the keyboard 7 is exposed to the front side (the outside) of the second housing 2C through the opening 2r. On the face 2a, the keyboard 7 is positioned nearer to the side of the end 2e, while the pointing device 8a and the click buttons 8b are arranged nearer to the side of the end 2c opposite the end 2e. The end 2e is positioned on the back side in a horizontal depth direction (a front-back direction), while the end 2c is positioned on the near side.

In the third embodiment, as an example, the second housing 2C houses, on the back side (the reverse side, the rear side, the side of the wall 2m, the side opposite the operation face 7a) of the keyboard 7, one or more substrate 6 (a circuit board, a control board, a main board, an electrical component, a first electrical component), as illustrated in FIG. 7. The substrate 6 is provided in parallel with the keyboard 7. The substrate 6 is spaced from the walls 2k, 2m, 2n, etc., that is, the substrate 6 is arranged with space (gaps) from the walls 2k, 2m, 2n, etc.

In the third embodiment, as an example, a plurality of components (not illustrated) such as a CPU, a graphic controller, power circuit parts, a PCH, a memory slot connector, an LCD connector, an I/O connector, a power coil, an element, and a connector, can be mounted on the substrate 6. A control circuit can comprise an image signal processing circuit, a tuner, an HDMI signal processor, an AV input terminal, a remote control signal receiving module, a controller, a selector, an on-screen display interface, a memory (a ROM, a RAM, an HDD, or an SSD, for example), a voice signal processing circuit, etc. The control circuit controls the output of images (moving images, still images, etc.) on the screen 4a of the display 4, the output of voice from a speaker (not illustrated), the emission of light from an LED (not illustrated), etc. The display 4, the speaker, the LED, etc., are examples of an output module.

In the third embodiment, as an example, a plurality of vent holes 2s that open in slit form and are positioned in a radial and circular manner are provided on the wall 2m (a first wall), as illustrated in FIG. 8. A fan unit 50C is provided at a position at which the vent holes 2s and the fan unit 50C are overlapped in a thickness direction of the second housing 2C in the second housing 2C, that is, in the vicinity of the end 2e.

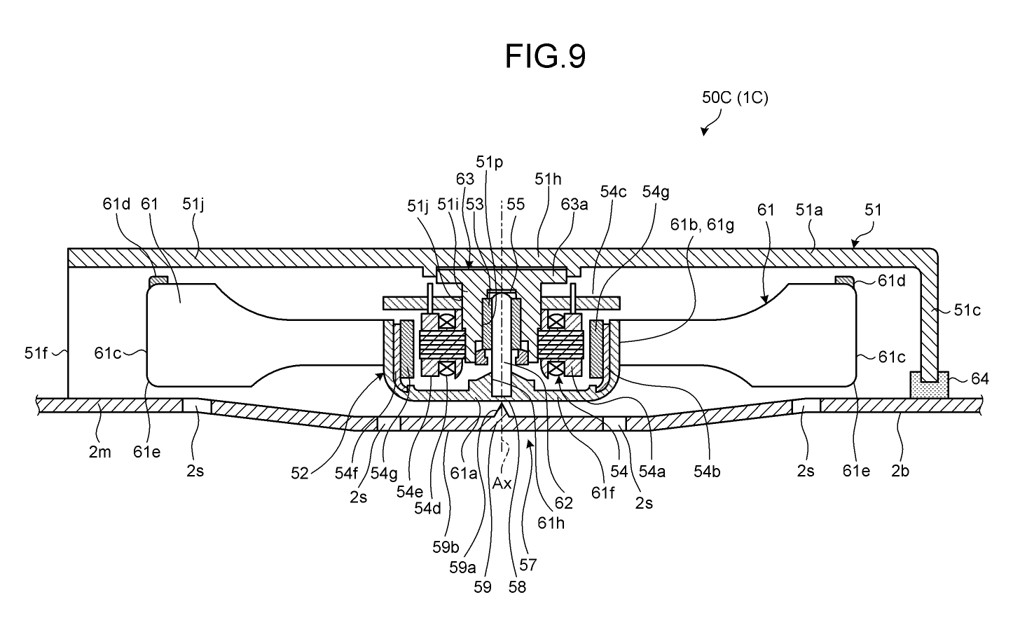

As is clear from comparison between FIG. 9 and FIG. 3, the configuration of the fan unit 50C in the third embodiment is the same as that of the fan unit 50A in the first embodiment. Therefore, also in the third embodiment, the same results (effects) based on the same structure as in the first embodiment can be obtained.

In the third embodiment, as an example, an elastic member 64 (a flexible member, a sealing member, a covering member, a cover) is provided between the wall 51c and the wall 2m (a first wall), as illustrated in FIG. 9. The elastic member 64 is formed by a flexible and elastic member such as synthetic resin materials (foaming resin materials, sponge, etc.), or elastomer (synthetic rubber, etc.). The elastic member 64 covers a gap between the wall 51c and the wall 2m, and seals the gap. Thus, the leak of air from the gap is prevented. Therefore, as an example, it is possible to prevent the deterioration of operating efficiency in operation (rotation of the fan 61) of the fan unit 50C and, in addition, the deterioration of cooling efficiency thereof. The elastic member 64 is flexible or elastic. Thus, even when position aberration occurs between the elastic member 64 and the wall 51c, the gap therebetween can be sealed. In addition, with elastic force, it is easier that contact pressure of the contact portion is increased and thus sealing performance is increased.

In the third embodiment, as an example, a portion of the wall 2m overlapping with the fan unit 50C is bulged (bended, folded) to the outer side of the second housing 2C, as illustrated in FIG. 9, so that the rigidness is increased. It is also possible to provide a vent hole on the wall 51a. In the electronic device 1C in the third embodiment, it is also possible to apply the fan unit 50B having the same structure as in the second embodiment.

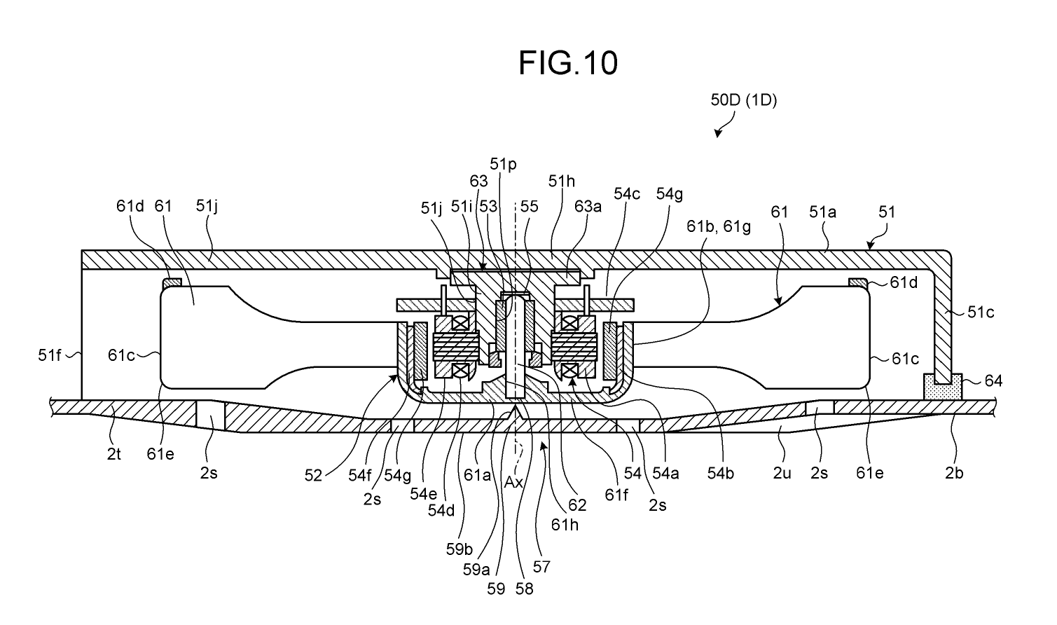

As is clear from comparison between FIG. 10 and FIG. 9, the configuration of a fan unit 50D housed in a second housing 2D of an electronic device 1D in a first modification is the same as that of the fan unit 50C in the third embodiment. Therefore, also in the first modification, the same results (effects) based on the same structure as in the third embodiment can be obtained.

However, in the first modification, as an example, reinforcing portions 2t and 2u are provided on the wall 2m, as illustrated in FIG. 10. The reinforcing portion 2t is a thicker portion as compared with other portions. The reinforcing portion 2u is a wall (a rib, a projecting portion) projecting to the outside of the housing of the wall 2m. Such reinforcing portions 2t and 2u can be appropriately provided on the wall 2m. The reinforcing portions can be also provided on the inside of the housing of the wall 2m.

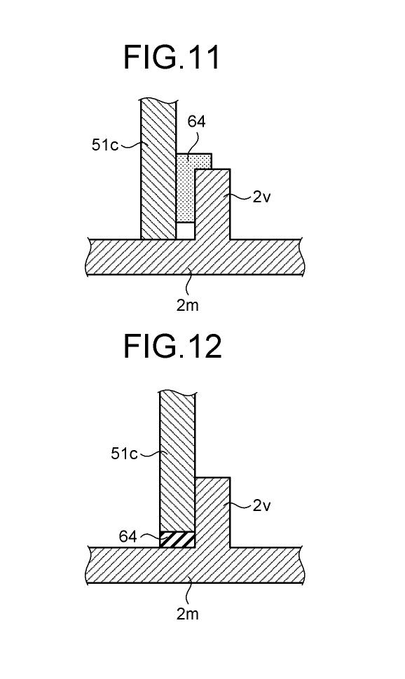

In a second modification, a wall 2v (a cover) is provided on the side of the wall 51c of the case component 51 opposite to (the right side in FIG. 11 of) the fan 61 (the rotation axis Ax (see FIG. 9)), as illustrated in FIG. 11. The elastic member 64 (a flexible member, a sealing member, a covering member, a covering portion) is provided between the wall 51c and the wall 2v. Also with such an arrangement, the same results (effects) as in the third embodiment can be obtained.

In a third modification, the elastic member 64 is provided between the wall 51c of the case component 51 and the wall 2m, as illustrated in FIG. 12. In addition, the elastic member 64 is in contact also with the wall 2v. Also with such an arrangement, the same results (effects) as in the third embodiment or the second modification can be obtained. The elastic member 64 can be attached, before assembling, to the wall 51c and one of the walls 2m and 2v by gluing, etc.

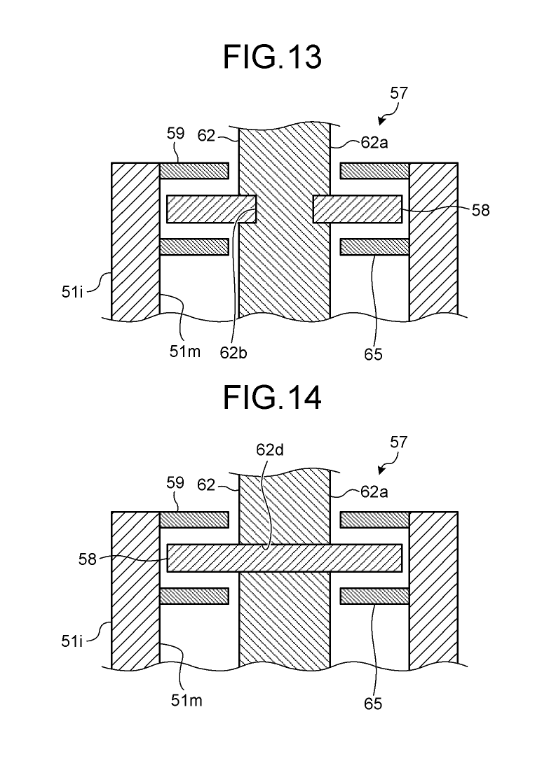

In a fourth modification, the movement restricting structure 57 is different from the other embodiments and the other modifications, as illustrated in FIG. 13. To be more specific, the movement restricting structure 57 is configured by the annular contact portion 58 (support portion) provided on the shaft 62 and inward and annular contact portions 65 (support portions) provided on the cylinder 51i. With such an arrangement, as an example, it is easier to make the thickness of the fan unit and then of the housing thinner as compared with a case in which the projecting portion 59a is provided on the walls 51c, 3m, and 2m.

In a fifth modification, the movement restricting structure 57 is different from the other embodiments and the other modifications, as illustrated in FIG. 14. To be more specific, the movement restricting structure 57 is configured by the contact portion 58 having a rod form provided so as to penetrate the shaft 62 and the inward and annular contact portions 65 provided on the cylinder 51i. Also with such an arrangement, as an example, it is easier to make the thickness of the fan unit and then of the housing thinner as compared with a case in which the projecting portion 59a is provided on the walls 51c, 3m, and 2m.

It is also possible to partially substitute the structure or form of each of the embodiments. The specification such as each structure or form (a structure, a kind, a direction, a form, a size, a length, a width, a thickness, a height, the number, arrangement, a position, a material, etc.) can be appropriately changed. The structures described herein can be applied even when the fan unit is provided not to the housing but to the substrate.

Moreover, the various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television receiver comprising:
a display comprising a screen;
a housing configured to house at least a portion of the display;
a fan opposite the screen with respect to the display, and configured to be rotatable in the housing;
a first wall of the housing comprising a vent hole overlapping with the fan, configured to cover the fan and a side of the display opposite the screen, and to constitute one portion of a case of the fan;
a second wall on an inner side of the housing with respect to the first wall and on a side of the fan opposite the first wall, configured to attach to the first wall, and to constitute other portion of the case of the fan; and
a third wall configured to extend between the first wall and the second wall.

2. The television receiver of claim 1, wherein
the third wall is configured to integrally project from the second wall, and
the television receiver further comprising a cover configured to cover a gap between the third wall and the first wall.

3. The television receiver of claim 2, comprising a flexible member as the cover.

4. The television receiver of claim 1, comprising a sealing member sandwiched between the first wall and an end of the third wall positioned on a side of the first wall, as a cover.

5. The television receiver of claim 1, wherein the third wall comprises a first part integrally projecting from the first wall and a second part overlapping with the first part in a radial direction of a rotation axis of the fan and integrally projecting from the second wall.

6. The television receiver of claim 1, wherein the first wall comprises a reinforcing portion.

7. The television receiver of claim 1, wherein the fan is configured to be rotatably supported by the second wall.

8. The television receiver of claim 1, wherein the fan is configured to be rotatably supported by the first wall.

9. A television receiver comprising:
a housing configured to house at least a portion of a display;
a fan in the housing;
a first wall of the housing comprising a vent hole overlapping with the fan and configured to constitute one portion of a case of the fan; and
a second wall in an inner side of the housing with respect to the first wall and on a side of the fan opposite the first wall, configured to constitute other portion of the case of the fan.

10. An electronic device comprising:
a housing comprising a circuit board;
a fan in the housing;
a first wall of the housing comprising a vent hole overlapping with the fan and configured to constitute a portion of a wall of a case of the fan on one side in an axis direction of the case of the fan; and
a second wall in an inner side of the housing from the first wall and configured to constitute a portion of a wall of the case of the fan on the other side in the axis direction of the case of the fan.
